(19) United States
(12) Patent Application Publication
(10) Pub. No.: US 2006/0037641 A1
(43) Pub. Date: Feb. 23, 2006

(54) Body part of a vehicle provided with a thin-film solar cell and the production thereof

(76) Inventors: Horst Kibbel, Erbach (DE); Johannes Konle, Voehringen (DE); Ulf Koeing, Ulm (DE); Harmut Presting, Blaustein (DE)

Correspondence Address: DAVIDSON, DAVIDSON & KAPPEL, LLC, 485 SEVENTH AVENUE, 14TH FLOOR, NEW YORK, NY, 10018, US

(21) Appl. No.: 10/524,497

(22) PCT Filed: Aug. 12, 2003
(86) PCT No.: PCT/EP03/08917

§ 371 Date: Aug. 15, 2005

(30) Foreign Application Priority Data
Aug. 16, 2002 (DE) 10238329.4
Oct. 16, 2002 (DE) 10247856.2

(51) Int. Cl. H01L 25/00

(52) U.S. Cl. 136/251; 136/244

(57) ABSTRACT

The invention relates to a body part of a vehicle provided with a support and with a transparent covering layer. A thin-film solar cell is applied to said support. The support, together with the thin-film solar cell, is covered by the transparent covering layer. The transparent covering layer consists of a paint layer, particularly a clear varnish layer. The thin-film solar cell is a CIS-, CIGS-, CIGSS-, CdTe- or an Si-based (particularly Si/SiGe) thin-film solar cell.

The typical construction of a bodywork part of a vehicle exhibits a carrier, which regularly comprises a shape-pressed steel panel. This carrier is provided with a plurality of coating layers having, in particular, a base coating, one color coating or a plurality thereof, and a transparent cover layer in the form of a clearcoat. These coatings, which are applied by means of immersion baths or spraying, afford a highly resistive protective layer for the carrier. Moreover, the bodywork part is distinguished by its particular esthetic effect.

It is known, moreover, to arrange solar cells in solar panels on houses. The companies Ebara Solar Inc. and United Solar Systems Corp. offer such solar panels in their range of products. The solar cells used therein constitute thin-film solar cells. Information about the product range and the method of operation can be obtained on the Internet page www.ebarasolar.com or www.unisolar.com.

It is an object of the invention to specify a bodywork part and a method for producing it which has an attractive esthetic effect and is suitable for providing energy.

This object is achieved by means of a bodywork part having the features of claim 1 and also by means of a method for producing a bodywork part having the features of claim 12.

The subclaims relates to advantageous developments.

The invention relates to a bodywork part of a vehicle, having a carrier made, in particular, of metal, preferably made of steel, or made of plastic. For protection and for achieving the desired optical and esthetic effect of the bodywork part, the latter is provided with a transparent cover layer made, in particular, of a scratchproof synthetic resin coating. This transparent cover layer ensures mechanical and chemical protection of the bodywork part. This ensures a special longevity of the bodywork part. According to the invention, between the carrier, which is optionally curved in regions, and the transparent cover layer, one or a plurality of thin-film solar cells are applied on the carrier.

It is thus possible to achieve a supply of energy by means of one or a plurality of thin-film solar cells integrated into the bodywork part and covered with a transparent cover layer, and thus to provide energy for the motor vehicle. This energy constitutes a regenerative energy which, in particular, is also available during stationary operation. The transparent cover layer is preferably formed as a clearcoat layer. The invention's selection of a thin-film solar cell, which preferably constitutes a copper indium diselenide thin-film solar cell (CIS thin-film solar cell; CuInSe₂) or a copper indium gallium selenide thin-film solar cell (CIGS thin-film solar cell; CuIn₁₋ₓGaₓSe₂) or a copper indium gallium sulfide selenide thin-film solar cell (CIGSS thin-film solar cell; CuIn₁₋ₓGaₓS_{y}Se_{2-y}), a CdTe thin-film solar cell or an Si/SiGe thin-film solar cell, makes it possible to specify a bodywork part of a vehicle which can be integrated into the vehicle manufacturing process and exhibits the required resistance. In this case, it is particularly significant that application of the thin-film solar cell to a glass carrier and covering of this glass arrangement with an additional glass cover layer in order to form a sandwich-like arrangement of a plurality of glass layers which protect the thin-film solar cell arranged in between from external harmful influences, as are known in solar modules for houses, is not the subject-matter of the invention. These arrangements cannot be integrated into a process for manufacturing a bodywork part for an automobile.

What have proved to be particularly worthwhile are thin-film solar cells according to CIS-, CIGS-, CIGSS-, CdTe- or else Si-based technology, as are known from the development of thin-film solar cells also for application in solar modules for use in house building.

In the case of the invention, it has proved to be particularly worthwhile to realize the thin-film solar cell not just as a single cell, but as a monolithic tandem cell or as multicells that typically exhibit different sensitivity to different spectral ranges of sunlight. This results in a very efficient utilization of the broadband light radiated in for conversion into electrical energy.

It has proved to be particularly worthwhile to arrange an intermediate layer made, in particular, of cadmium sulfide (CdS) or of zinc selenide (ZnSe) between the transparent cover layer and the thin-film solar cell. Introducing a thin intermediate layer of this type significantly increases the efficiency of the solar cell. Moreover, it is possible to protect the sensitive solar-active layers of the cell, by means of the intermediate layer, still further from disturbing external influences, in particular chemical or mechanical influences, which result from the driving operation of a vehicle. In this case, the intermediate layer is preferably applied by means of CBD (chemical bath deposition), CVD (chemical vapor deposition) or PVD (physical vapor deposition). The intermediate layer used typically has a thickness of less than 50 nm. The preferred deposition of the intermediate layer in a chemical bath (CBTD) ensures that the surface of the solar-active layers of the solar cell, the roughness of which is significantly greater than the buffer layer thickness, is completely covered and the particular protection and the buffer effect are thereby avoided. These properties make it possible to specify a bodywork part having a solar cell with high efficiency and high quality and durability. In particularly preferred systems, a suitable selection of the intermediate layer makes it possible to increase the efficiency from 4% to more than 8%.

In order that the resistance of the bodywork part having one or more thin-film solar cells is improved even further, it has proved to be worthwhile to provide a layer made of Tefzel below the transparent cover layer and above the thin-film solar cell. Tefzel is a product from the company DuPont. It constitutes an ethylene tetrafluorethylene copolymer (ETFE). The use of Tefzel, which is applied in particular as a film to the carrier with thin-film solar cell, makes it possible to realize a very resistive and durable bodywork part with thin-film solar cell. This resistance is achieved without significantly impairing the efficiency of the solar cell. Besides the mechanical or chemical protection, the Tefzel layer ensures protection from undesirable aging of the solar-active cell. In this case, the flexible structure and the low relative density of Tefzel results in particular suitability for automobile construction.

It has proved to be particularly worthwhile to structure the carrier of a bodywork part made of metal to the effect that it can be used as an electrode for the thin-film solar cell. This makes it possible to realize a very simple construction of the bodywork part having one or a plurality of thin-film solar cells and thereby to lower the costs for the bodywork part with thin-film solar cell.

According to another preferred embodiment of the invention, a separating layer is arranged between the thin-film solar cell and the carrier made of metal, in particular made of steel. The separating layer is preferably made of polyimide or room temperature cross linking silicone (RTC silicone). This separating layer affords, on the one hand, an electrical insulation of the thin-film solar cell from the carrier but also, on the other hand, a very efficient encapsulation of the thin-film solar cell in particular in conjunction with a layer made of Tefzel, which enables a particular mechanical and chemical protection of the thin-film solar cell. Furthermore, the separating layer affords compensation between the different thermal expansion behavior of the carrier and the thin-film solar cell. This is particularly significant precisely in the case of a carrier made of steel. It has proved to be particularly advantageous to apply the polyimide layer to the carrier, which preferably comprises sheet steel, by means of spraying on or spinning on. Spraying on, in particular, has proved to be particularly worthwhile in vehicle construction.

As electrical contacts for the thin-film solar cell, provision has preferably been made of indium tin oxide (ITO) for the upper electrodes and copper, steel, Kovar or molybdenum for the lower electrodes. This use of special electrode materials affords a highly effective thin-film solar cell that is also suitable for use in the automotive field. In this case, indium tin oxide proves to be a very advantageous upper electrode since it absorbs sunlight only insignificantly, so that the active layer of the thin-film solar cell can convert the light energy into electrical energy very efficiently. The electrodes are preferably sputtered on or applied by vapor deposition.

By virtue of the electrode materials used, besides the protective layers provided, in particular by virtue of the transparent cover layer preferably made of scratchproof synthetic resin coating, what is achieved is an inherently insufficient, but in combination highly advantageous mechanical and chemical protective effect.

The use of a color layer in the region above the active layers of the thin-film solar cell, in particular in the region of the Tefzel layer or the intermediate layer or the transparent cover layer, makes it possible to achieve a very pleasant, esthetically pleasing impression of the bodywork part with thin-film solar cell which can esthetically go well together with the other bodywork parts of the vehicle. The use of suitable color layers, formed particularly by the Tefzel layer, the intermediate layer and/or the transparent cover layer, makes it possible to achieve the same uniform color impression for the bodywork part as is provided for the rest of the vehicle. This makes it possible not only to provide a highly functional bodywork part but also to provide an esthetically very appealing and thus readily saleable bodywork part and thus also a very attractive vehicle with such a bodywork part.

Furthermore, besides the possibility of exclusively providing a separate color layer for creating an attractive exterior configuration, it is possible supplementarily or independently to bring about specific color impressions in a targeted manner through selection of the layer thickness or selection of individual layers of the thin-film solar cell. If a CdS thin-film solar cell having a layer thickness that is not too thin is selected, then a greenish color impression arises on account of a band gap in the region of 2.5 eV, whereas the use of a CIS or CIGSS thin-film solar cell gives rise to a reddish color impression on account of the band gap in the region of 1 eV or 1.55 eV. A bluish color impression can be achieved by using a ZnO layer. A wide variety of color impressions can be achieved through combination of these layers in different layer thicknesses and through the possible supplementation with an additional color layer. The utilization of this color effect of specific layers of the thin-film solar cells had not been desired and had also accordingly not been used previously.

Bodywork parts having a curved surface which have been produced by the method according to the invention for producing such a bodywork part according to the invention are of particular significance. In contrast to a prefabricated thin-film solar cell, such as are known from prefabricated solar modules for house building, the method according to the invention for producing a bodywork part according to the invention also makes it possible to realize ones having curved surfaces, which considerably extends the use of such thin-film solar cells. By way of example, the invention makes it possible to realize sheetlike, curved bodywork parts, such as vehicle roofs, boot lids, bonnets, wings, doors or else bumpers.

According to the method according to the invention for producing a bodywork part, after the production of the carrier in particular by reshaping of steel plates, the various layers of the thin-film solar cell are applied step by step. In this case, in particular the additional layers such as the polyimide layer, the intermediate and/or the Tefzel layer are applied prior to the application of a transparent cover layer. The transparent cover layer is preferably applied as a synthetic resin coating in the context of an immersion bath of the bodywork part. This production of the bodywork part realizes a highly functional and resistive bodywork part with solar cell.

The invention is explained below on the basis of an exemplary construction of a bodywork part.

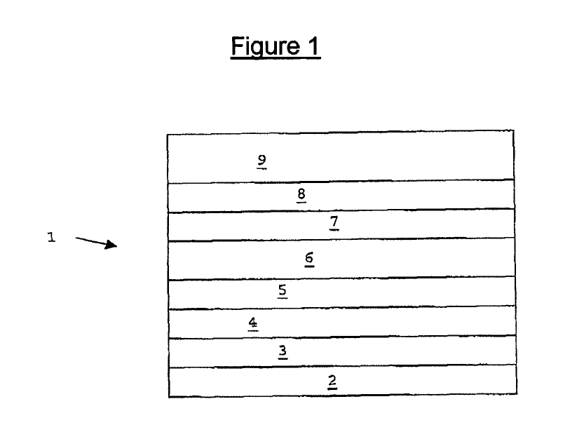

FIG. 1 shows the construction of a bodywork part 1.

The bodywork part 1 exhibits a carrier 2 made of a bodywork metal sheet comprising steel. A polyimide layer 3 is applied to the carrier 2 by means of spraying. Said polyimide layer 3 is provided for electrical insulation and for mechanical and chemical encapsulation of the subsequent thin-film solar cell. The polyimide layer 3 is followed by the lower electrode 4, which is formed from molybdenum. The lower electrode 4 made of molybdenum was realized by being sputtered on. The lower electrode 4 is followed by the solar-active np layer sequence 6, 5. This thin-film solar cell is of the CIGSS type; in this case, the p-doped layer 5 is formed from a copper (Cu)—indium (In)—gallium (Ga)—selenium (Se)—sulfur (S)—crystal, while the n-doped layer 6 is formed from cadmium sulfide. The upper electrode 7 is formed by n-doped indium tin oxide (ITO). The indium tin oxide layer 7 constitutes a transparent electrical contact that is applied to the solar-active layers 5, 6 by means of vapor deposition. On account of its transparency, it transmits the sunlight largely unimpeded, so that the latter can be converted into electrical energy by the solar-active layers 5, 6 and be conducted away by the two electrodes 4, 7.

The solar-active layers 5, 6 are enclosed by the electrodes 4, 7 and the polyimide layer 3 and also above by a Tefzel layer 8. This enclosure affords an encapsulation and thus a mechanical and chemical protection of the thin-film solar cell, which leads to a very durable, resistive and effective arrangement comprising bodywork part with carrier and thin-film solar cell. This resistance is improved even further by a transparent, scratchproof synthetic resin coating 9, which is applied in particular by means of an immersion bath, which, moreover, leads to the bodywork part having an improved resistance to corrosion. The clearcoat used results in a largely uniformly optical effect of the bodywork part 1 in interaction with the other bodywork parts of the vehicle which are coated with the same clearcoat. Furthermore, a suitable coloration of the clearcoat 9 results in an adapted optical color effect of the bodywork part 1 with thin-film solar cell in relation to the other bodywork parts of the vehicle.

By means of an adapted arrangement of the various cells of the thin-film solar cell and an appropriate contact-connection of the different cells to one another, solar cell arrangements having a desired output voltage and energy density can be achieved in particular by an appropriate interconnection of the cells by means of a so-called via hole contact-connection of the upper layer electrodes 7 to the lower layer electrodes 4.

To summarize, it shall be emphasized that the invention's realization of a bodywork part with thin-film solar cell affords a highly functional bodywork part which, besides the function of supplying energy by converting the solar energy into electrical energy, also realizes the requirements made of mechanical and chemical resistance and also the requirements made of esthetic effect in an advantageous manner.

1-12. (canceled)

13. A bodywork part of a vehicle, comprising:
a carrier made of metal;
at least one thin-film solar cell disposed on the carrier;
a transparent cover layer covering the at least one thin-film solar cell and the carrier, wherein the carrier forms an electrode of the thin-film solar cell.

14. The bodywork part as recited in claim 13, wherein the carrier made of steel.

15. The bodywork part as recited in claim 13, wherein the transparent cover layer includes a coating layer.

16. The bodywork part as recited in claim 15, wherein the coating layer includes a clearcoat.

17. The bodywork part as recited in claim 13, wherein the thin-film solar cell includes at least one of a CIS-, a CIGS-, a CIGSS-, a CdTe- and a Si-based thin-film solar cell.

18. The bodywork part as recited in claim 13, further comprising an intermediate layer disposed between the transparent cover layer and the thin-film solar cell.

19. The bodywork part as recited in claim 18, wherein the intermediate layer includes at least one of CdS or ZnSe.

20. The bodywork part as recited in claim 13, further comprising a layer made of Tefzel is disposed between the transparent cover layer and the thin-film solar cell.

21. The bodywork part as recited in claim 13, further comprising upper electrodes formed using indium tin oxide and lower electrodes formed using at least one of copper, aluminum, steel, Kovar and molybdenum, the upper and lower electrodes serving as electrical contacts for the thin-film solar cell.

22. The bodywork part as recited in claim 20, wherein a color layer is provided on a side of the thin-film solar cell assigned to the transparent cover layer.

23. The bodywork part as recited in claim 22, wherein the color layer is formed by one of the transparent cover layer and the layer made of Tefzel.

24. The bodywork part as recited in claim 13, wherein the carrier has a curved surface.

25. The bodywork part as recited in claim 24, wherein the bodywork part is a part of one of a vehicle roof, a boot lid, a bonnet, a wing, a door and a bumper.

26. A method for producing a bodywork part of a vehicle, the method comprising:
providing a metallic carrier;
applying at least one thin-film solar cell on the carrier;
applying a transparent cover layer so as to cover the at least one thin-film solar cell and the carrier; and
using the metallic carrier as an electrode of the thin-film solar cell.

27. The method as recited in claim 26, wherein the transparent cover layer includes a clearcoat.
